(19) United States
(12) Patent Application Publication
(10) Pub. No.: US 2026/0004842 A1
(43) Pub. Date: Jan. 1, 2026

(54) CIRCUIT FOR MULTIPORT REGISTER FILE

(71) Applicant: Arm Limited, Cambridge (GB)

(72) Inventors: Rahul MATHUR, Austin, TX (US); Andy Wangkun CHEN, Austin, TX (US); Yew Keong CHONG, Austin, TX (US); Parveen KUMAR, Ghaziabad (IN)

(21) Appl. No.: 18/755,149

(22) Filed: Jun. 26, 2024

(51) Int. Cl. G11C 11/419; G11C 5/06; G11C 5/14

(52) U.S. Cl. CPC G11C 11/419; G11C 5/066; G11C 5/147

(57) ABSTRACT

Various implementations described herein are related to a read multiplexer circuit for a multiport register file, comprising: an input stage coupled to an array of storage nodes, each storage node coupled to drive an output of a respective bitcell; a read stage comprising control logic dividing the array of storage nodes into one or more sets and first circuitry that provides a first read word line to a first storage node of a first set for reading data from the first storage node and a second read word line to a second storage node of the first set for reading data from the second storage node; and a first latch stage comprising second circuitry that provides a third read word line to the first and second storage node of the first set to latch the read from one of the first and second storage nodes.

### FIELD

The present technology relates to a bitcell architecture and read multiplexer circuit for a multiport register file.

### BACKGROUND

In conventional semiconductor fabrication designs, multi-port memory designs suffer from routing congestion issues such as crosstalk. Also, bitcell area is increasing on modern designs that typically degrade performance and increase power, which often causes additional inefficiencies in common bitcell designs. Multi-port memory designs are often limited to a fixed number of read ports, with additional read ports requiring modification of the bitcell. Therefore, to overcome the deficiencies of conventional bitcell designs, improved multi-port memory circuits having more efficient multi-port bitcell designs are needed to improve routing congestion, crosstalk, provide scalability of read ports and to reduce area of integrated circuitry.

### SUMMARY

According to a first aspect of present techniques, there is provided a read multiplexer circuit for a multiport register file, comprising: an input stage coupled to an array of storage nodes, each storage node coupled to drive an output of a respective bitcell; a read stage comprising control logic dividing the array of storage nodes into one or more sets and first circuitry that provides a first read word line to a first storage node of a first set for reading data from the first storage node and a second read word line to a second storage node of the first set for reading data from the second storage node; and a first latch stage comprising second circuitry that provides a third read word line to the first and second storage node of the first set to latch the read from one of the first and second storage nodes.

Accordingly, a multiport register file is provided with separate write and read ports, whereby the read ports are formed in a read multiplexer circuit coupled to the output of the bitcells. A new architecture allows for variation in the number of read ports to suit user requirements, for example, increasing the number of read ports from 9 to 18 on a single macro. The present architecture is scalable by increasing or decreasing read port number without having to modify a bitcell. During a write operation, the storage node activity may be blocked at the read multiplexer input saving write power. Since there is less coupling between line traces, critical timing signals are protected and coupling is mitigated between, for example, read word line (RWL) and write word line (WWL) and on read bit line (RBL) from write bit line (WBL).

In embodiments and in one non-limiting example operation, during a write operation a write wordline (WWL) is operated, which transfers a flopped data (WBL) onto a storage cross-couple and storage node output. Storage node outputs from all bitcells from different rows are multiplexed and latched in the read multiplexer circuit.

Preferably, the first read word line is shared with a first storage node of a second set and the second read word line is shared with a second storage node of the second set for reading data from the first and second storage nodes of the second set respectively. In present embodiments, the first read word line is shared with multiple sets of storage nodes and the second read word line is shared with multiple sets of storage nodes.

As an example, in present embodiments the read multiplexer circuit may have a first read word line shared with a first storage node of a third set and the second read word line shared with a second storage node of the third set for reading data from the first and second storage nodes of the third set respectively. Additionally or alternatively, the read multiplexer circuit may have a first read word line shared with a first storage node of a fourth set and the second read word line shared with a second storage node of the fourth set for reading data from the first and second storage nodes of the fourth set respectively.

Further, in present embodiments, the first circuitry that provides a first read word line to the first storage node comprises a first transistor and a second transistor coupled in series between a source voltage and a reference voltage. Preferably, the first transistor is activated by the first read word line and the second transistor is activated by a logical inversion of the first read word line.

In embodiments, a third transistor is coupled between the second transistor and the source voltage and a fourth transistor is coupled between the second transistor and the reference voltage. In embodiments, any transistor such as a first transistor is a n-type transistor and the second transistor is a p-type transistor.

In present techniques, the first latch stage comprising second circuitry such that the first read word line is coupled between the first transistor and the second transistor. Preferably, the first latch stage is coupled to control logic that coordinates read operations provided by a read port line coupled from the first read stage to the control logic to determine an output state of stored data. In embodiments, the circuit includes a second latch stage comprising third circuitry that provides a fourth read word line to a first and second storage node of a different set to the first set to latch the read from one of the first and second storage nodes of that different set according to an address specifying a location of the storage node in the read multiplexer circuit. In embodiments, the read multiplexer circuit comprises multiple sets and wherein each set is coupled to an individual latch circuit.

The output of the bitcell may be driven by an inverter, wherein an inverter is coupled to an output of a bitcell to drive storage node output of the bitcell. Preferably, address information is encoded with a read word line. One of Read Word Line [0-3] and one of Read Word Line_BNK[0-3] may toggle once to pass the appropriate storage node value to read bit line (RBL) according to an address specifying a location of the storage node in the read multiplexer circuit.

According to a second aspect of present techniques, there is provided a circuit for a multiport register file comprising: an array of multiple storage nodes, each having a bitcell; a two-stage read multiplexer circuit configured to receive an output of each storage node in the array of multiple storage nodes, comprising: a read stage for selecting data from the storage node output; a first latch stage for storing the selected data; control logic for coordinating read operations from multiple ports.

Preferably, a driver is coupled to the output of each storage node and coupled to an input of the two-stage read multiplexer circuit. In embodiments, the driver is provided by an inverter coupled to the output of a bitcell to drive storage node output of the bitcell. Preferably, the circuit for a multiport register file comprises control logic dividing the array of storage nodes into sets and first circuitry that provides a first read word line to a first storage node of a first set for reading data from the first storage node and a second read word line to a second storage node of the first set for reading data from the second storage node. Preferably, the first read word line is shared with multiple sets of storage nodes and the second read word line is shared with multiple sets of storage nodes. Preferably, the first latch stage is coupled to control logic that coordinates read operations provided by a read port line coupled from the read stage to the control logic to determine an output state of stored data. Techniques include a second latch stage comprising third circuitry that provides a fourth read word line to a first and second storage node of a different set to the first set to latch the read from one of the first and second storage nodes of that different set according to an address specifying a location of the storage node in the circuit.

According to a third aspect of present techniques, there is provided a non-transitory computer-readable medium to store computer-readable code for fabrication of any circuitry described herein.

Accordingly, concepts described herein may be embodied in computer-readable code for fabrication of an apparatus that embodies the described concepts. For example, the computer-readable code can be used at one or more stages of a semiconductor design and fabrication process, including an electronic design automation (EDA) stage, to fabricate an integrated circuit comprising the apparatus embodying the concepts. The above computer-readable code may additionally or alternatively enable the definition, modelling, simulation, verification and/or testing of an apparatus embodying the concepts described herein.

For example, the computer-readable code for fabrication of an apparatus embodying the concepts described herein can be embodied in code defining a hardware description language (HDL) representation of the concepts. For example, the code may define a register-transfer-level (RTL) abstraction of one or more logic circuits for defining an apparatus embodying the concepts. The code may define an HDL representation of the one or more logic circuits embodying the apparatus in Verilog, SystemVerilog, Chisel, or VHDL (Very High-Speed Integrated Circuit Hardware Description Language) as well as intermediate representations such as FIRRTL. Computer-readable code may provide definitions embodying the concept using system-level modelling languages such as SystemC and SystemVerilog or other behavioural representations of the concepts that can be interpreted by a computer to enable simulation, functional and/or formal verification, and testing of the concepts.

Additionally, or alternatively, the computer-readable code may define a low-level description of integrated circuit components that embody concepts described herein, such as one or more netlists or integrated circuit layout definitions, including representations such as GDSII. The one or more netlists or other computer-readable representation of integrated circuit components may be generated by applying one or more logic synthesis processes to an RTL representation to generate definitions for use in fabrication of an apparatus embodying the invention. Alternatively, or additionally, the one or more logic synthesis processes can generate from the computer-readable code a bitstream to be loaded into a field programmable gate array (FPGA) to configure the FPGA to embody the described concepts. The FPGA may be deployed for the purposes of verification and test of the concepts prior to fabrication in an integrated circuit or the FPGA may be deployed in a product directly.

The computer-readable code may comprise a mix of code representations for fabrication of an apparatus, for example including a mix of one or more of an RTL representation, a netlist representation, or another computer-readable definition to be used in a semiconductor design and fabrication process to fabricate an apparatus embodying the invention. Alternatively, or additionally, the concept may be defined in a combination of a computer-readable definition to be used in a semiconductor design and fabrication process to fabricate an apparatus and computer-readable code defining instructions which are to be executed by the defined apparatus once fabricated.

Such computer-readable code can be disposed in any known transitory computer-readable medium (such as wired or wireless transmission of code over a network) or non-transitory computer-readable medium such as semiconductor, magnetic disk, or optical disc. An integrated circuit fabricated using the computer-readable code may comprise components such as one or more of a central processing unit, graphics processing unit, neural processing unit, digital signal processor or other components that individually or collectively embody the concept.

Implementations of the present technology each have at least one of the above-mentioned objects and/or aspects, but do not necessarily have all of them. It should be understood that some aspects of the present technology that have resulted from attempting to attain the above-mentioned object may not satisfy this object and/or may satisfy other objects not specifically recited herein.

Additional and/or alternative features, aspects and advantages of implementations of the present technology will become apparent from the following description, the accompanying drawings and the appended claims.

### BRIEF DESCRIPTION OF THE DRAWINGS

Implementations of various techniques are described herein with reference to the accompanying drawings. It should be understood, however, that the accompanying drawings illustrate only various implementations described herein and are not meant to limit embodiments of various techniques described hereon. Embodiments will now be described, with reference to the accompanying drawings, in which:

FIG. 1 shows a multi-port bitcell macro;

FIG. 2 shows a storage node configured as a multi-transistor bitcell;

FIG. 3 shows a modified multi-port bitcell macro;

FIG. 4 shows a modified bitcell circuit; and

FIG. 5 shows a read multiplexer circuit;

### DETAILED DESCRIPTION

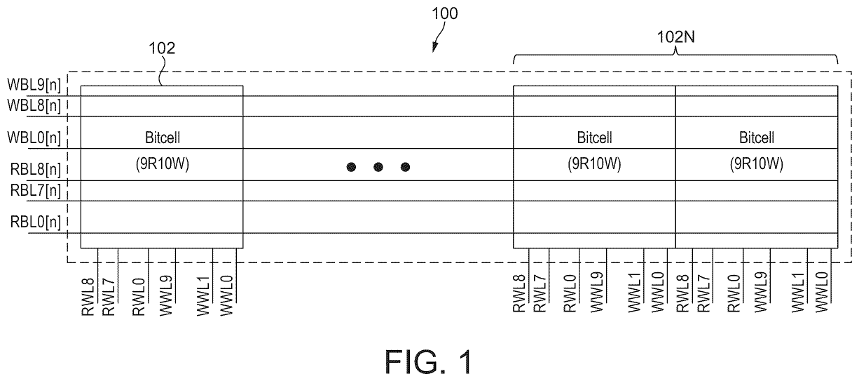

FIG. 1 shows a multi-port bitcell macro 100 which may be implemented as a system or device having integrated circuitry (IC) and various components arranged and coupled together as an assemblage or some combination of parts that may provide for physical circuit layout design and related structures. In various applications, a method of designing, fabricating, building and/or providing the multi-port bitcell macro 100 as an integrated system or device may involve use of IC circuit components described herein to implement various configurable multi-port bitcell architecture schemes and/or techniques associated therewith. Moreover, the multi-port bitcell macro 100 may be integrated with various computing circuitry and related components on a single chip, and further, the multi-port bitcell macro 100 may be implemented within various embedded systems for automotive, electronic, mobile, server, PC, gaming and Internet-of-things (IoT) applications, include remote sensor nodes.

Multiple bitcells 102-102N are arranged in rows although only three bitcells are shown in FIG. 1 and the multi-port bitcell macro 100 comprises 9 read ports and 10 write ports. As seen in FIG. 1, multiple Read Bitlines (RBL) and Write Bitlines (WBL) are provided to each bitcell 102-102N with multiple Read word lines (RWL) and Write WordLines (WWL).

Multi-port memory designs suffer from routing congestion issues and coupling between the multiple Read Bitlines (RBL) and Write Bitlines (WBL) and between the Read word lines (RWL) and Write WordLines (WWL).

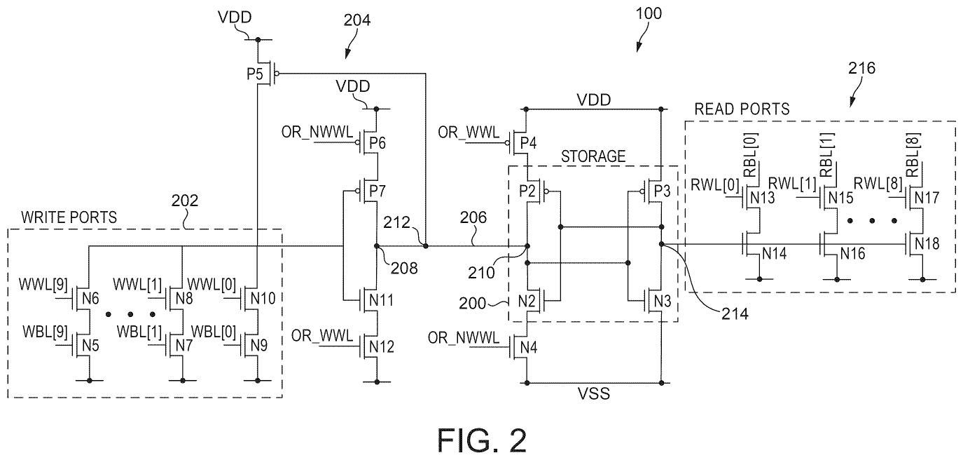

As shown in FIG. 2, the multi-port bitcell macro 100 comprises a storage node 200 configured as a multi-transistor bitcell, such as a four transistor (4T) tri-stated bitcell. Also, the storage node 200 is implemented as a static random access memory (SRAM) structure that is configured to store at least one data-bit value such as a data value related to a logical “0” or “1”. The storage node 200 has multiple transistors (P2/N2, P3/N3) that are coupled together as cross-coupled inverters, wherein a first inverter (P2/N2) has transistor (P2) coupled in series with transistor (P4) and a source voltage (VDD). Transistor (N2) is coupled in series with transistor (N4) and ground (VSS or Gnd). A second inverter (P3/N3) has transistor (P3) coupled in series with transistor N3 between source voltage (VDD) and ground (VSS or Gnd).

The multi-port bitcell macro 100 comprises an input stage 202 comprising write ports including an array of transistors arranged in columns. First column comprises a transistor (N5) coupled in series with transistor (N6) wherein the drain terminal of transistor (N5) is coupled to ground (VSS or Gnd) and the source terminal of transistor N6 is coupled to a control stage 204. Second column comprises a transistor (N7) coupled in series with transistor (N8) wherein the drain terminal of transistor (N7) is coupled to ground (VSS or Gnd) and the source terminal of transistor (N8) is coupled to a control stage 204. Third column comprises a transistor (N9) coupled in series with transistor (N10) wherein the drain terminal of transistor (N9) is coupled to ground (VSS or Gnd) and the source terminal of transistor (N10) is coupled to pre-charge transistor (P5) coupled the between the source voltage (VDD) and the transistor (N10) and a gate terminal of transistor (P5) coupled to a node 212 which is coupled to the storage node 200 by way of a node 210. The pre-charge transistor (P5) is a p-type transistor.

The input stage 202 comprises columns of write wordline (WWL) ports and and write bitline (WBL) ports coupled to the input stage 202. In FIG. 2, three write ports are illustrated out of ten write ports according to present techniques.

The control stage 204 comprises a transistor (P6) coupled in series between source voltage (VDD) and transistor (P7). Transistor (P7) is coupled in series with transistor (N11). A gate terminal of transistor (P7) is coupled to the gate terminal of transistor (N11). Transistor (N11) is coupled in series with transistor (N12). Transistor (N12) is coupled in series between transistor (N11) and ground (VSS or Gnd). The control stage is configured to perform a first write based on an internal bitline signal and a first write worldline signal (OR_NWWL) and a second write worldline signal (OR_WWL). The control stage 204 outputs the internal bitline signal as an output signal when activated by the first write worldline signal (OR_NWWL) and the second write worldline signal (OR_WWL).

The control stage 204 is coupled to the storage node 200 by way of a trace 206 coupled to a node 208 located between the drain terminal of transistor (P7) and source terminal of transistor (N11) and coupled to the node 210 located between the first inverter (P2/N2). Additionally, the gate terminal of transistor (P5) is coupled to the trace 206 at the node 212 located between an output of the control stage 204 and input to the storage node 200. Also, the second write wordline signal (OR_WWL) is coupled to the gate terminal of transistor (P4) for activation by the second write wordline signal (OR_WWL). Further, the first write wordline signal (OR_NWWL) is coupled to the gate terminal of transistor (N4) for activation by the first write wordline signal (OR_NWWL).

The write wordline (WWL) ports and write bitline (WBL) ports provide an internal bitline signal to the control stage 204 when activated by the selected write wordline (WWL) signal from at least one write wordline (WWL) port of the write wordline (WWL) ports and also when activated by the selected write bitline (WBL) signal on at least one write bitline (WBL) port of the write bitline (WBL) ports.

The storage node 200 has output node 214 coupled to output stage 216 including read ports. The output stage 216 comprises columns of read wordlines (RWL) and read bitlines (RBL).

A first read port comprises a transistor N13 coupled in series with a transistor N14. Transistor N13 is coupled to address a read bitline 0 (RBL) at a source terminal and a gate terminal is coupled to address a read word line 0 (RWL). Transistor N14 is coupled to ground (VSS or Gnd).

A second read port comprises a transistor N15 coupled in series with a transistor N16. Transistor N15 is coupled to address a read bitline 1 (RBL) at a source terminal and a gate terminal is coupled to address a read word line 1 (RWL). Transistor N14 is coupled to ground (VSS or Gnd).

A ninth read port comprises a transistor N17 coupled in series with a transistor N18. Note that in FIG. 2, read ports three to eight are not illustrated. Transistor N17 is coupled to address a read bitline 8 (RBL) at a source terminal and a gate terminal is coupled to address a read word line 8 (RWL). Transistor N14 is coupled to ground (VSS or Gnd). As such, present techniques disclose nine read ports and ten write ports on macro 100.

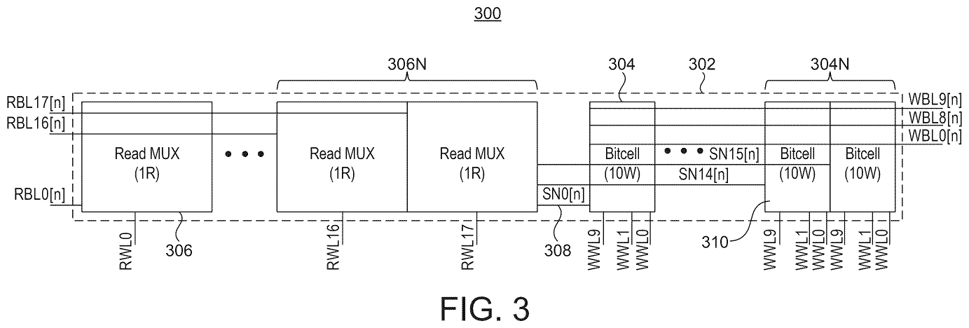

Referring to FIG. 3, a multi-port bitcell macro 300 according to present techniques shows a modified multi-port register file 302. According to the modified multi-port register file 302, the read and write functions are separated compared to the embodiment disclosed in accordance with FIGS. 1 and 2.

Multiple bitcells 304-304N are arranged in rows although only three bitcells are shown in FIG. 3 and the multi-port bitcell macro 300 comprises eighteen read ports (RWL, RBL) and ten write ports (WWL, WBL) in contrast to the embodiment disclosed in accordance with FIGS. 1 and 2 which comprised nine read ports and ten write ports.

There are no read ports provided on the multi-port bitcell macro 300 and in their place are ReadMUX circuits 306-306N coupled to a storage node 308 of each bitcell 310. Each ReadMUX circuit 306-306N is coupled to a read bitline and read wordline, then by way of a connection to the storage node 308 of each bitcell 310 is configured to read a state of the storage node 308, wherein each bitcell 310 is coupled to both a write wordline and a write bitline.

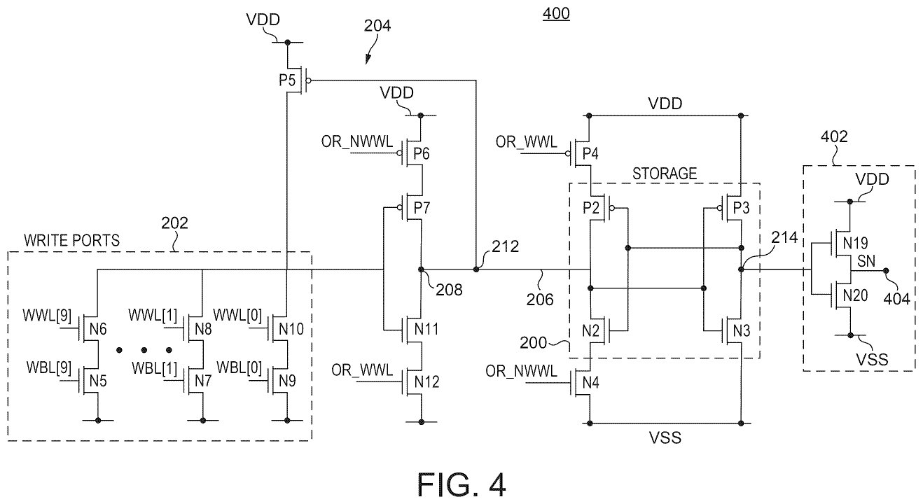

FIG. 4 shows in more detail a modified bitcell circuit 400 according to present techniques. Throughout FIG. 4, like parts are designated with like reference numerals according to FIG. 2. As can be seen in FIG. 4, the storage node 200, the input stage 202 and the control stage 204 are the same in FIG. 4 and in FIG. 2. In FIG. 2, the storage node 200 has output node 214 coupled to output stage 216 including read ports. The output stage 216 comprises columns of read word lines (RWL) and read bitlines (RBL).

In contrast to FIG. 2, the output node 214 is not coupled to an output stage 216 including read ports because all the read ports have been removed from the modified bitcell circuit 400. An inverter 402 is coupled to the output node 214 to drive storage node 200 output. The inverter 402 comprises transistor N19 coupled in series to transistor N20. A gate terminal of transistor N19 is coupled to a gate terminal of transistor N20 and both gate terminals are coupled to the output node 214. The transistor N19 is coupled to the source voltage (VDD) and the transistor N20 is coupled to ground (VSS or Gnd). Storage node output 404 is coupled between the drain and source terminal of the transistor N19 and transistor N20 respectively and is coupled to a ReadMux circuit (not shown in FIG. 4).

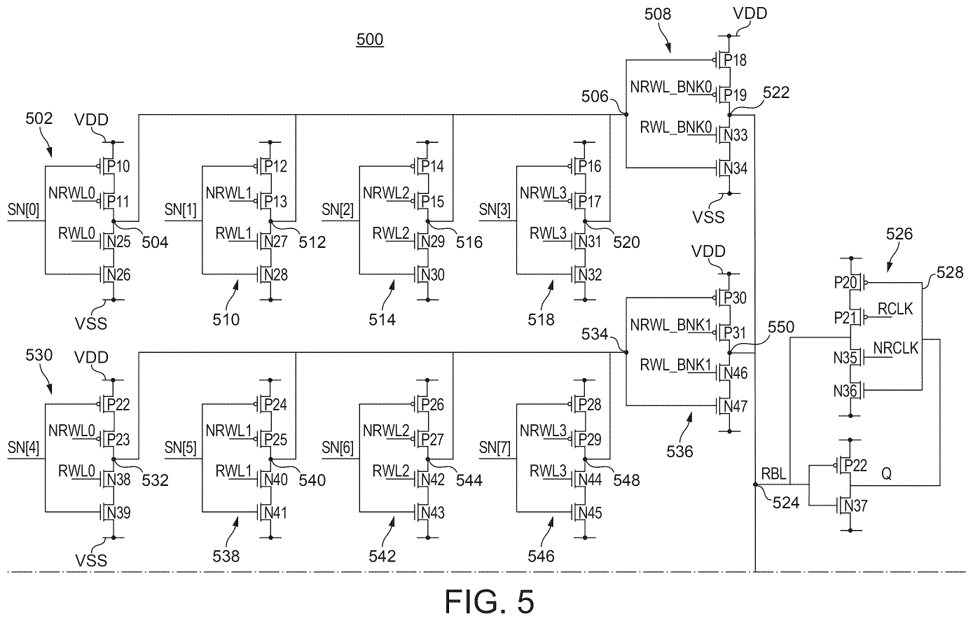

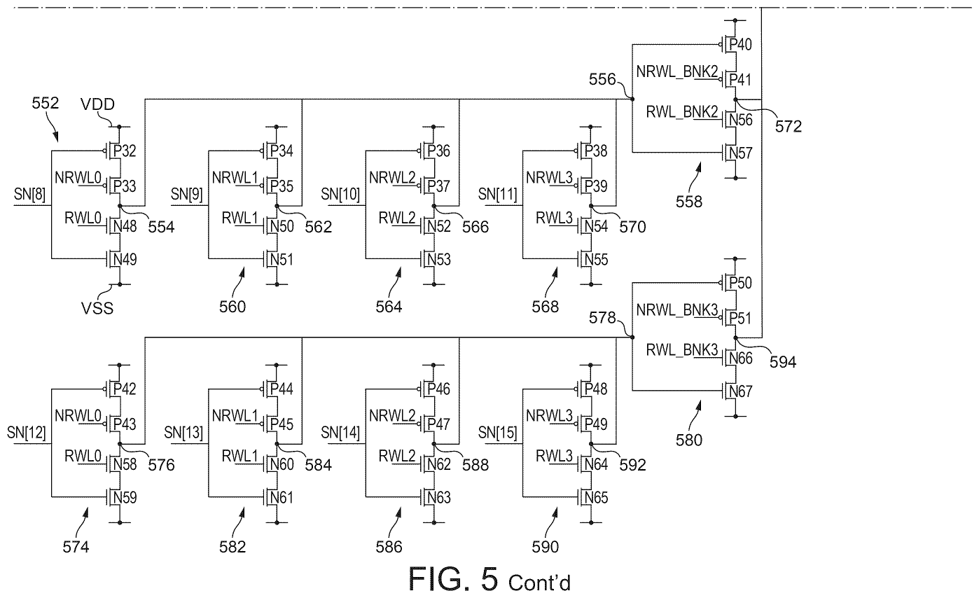

During a write operation, the write wordline (WWL) is activated, which transfers a flopped data (WBL) onto the storage node 200 and storage node output 404. Storage node outputs from all bitcells from different rows are multiplexed and latched in the ReadMux circuit described in more detail in FIG. 5.

FIG. 5 shows a read multiplexer circuit 500 that provides selection signals to the storage node outputs from all bitcells described in accordance with FIGS. 3 and 4.

In the following, reference to zero is made because the storage nodes and lines are counted starting from zero. In the following, reference to a negative line such as a negative read wordline is reference to a logical inversion of the line. For example, a negative read wordline is a logical inversion to a read wordline.

A zero storage node output SN[0] is coupled to a first stage multiplexer circuit comprising zero-input stage 502. Zero input stage 502 comprises transistor (P10) coupled in series with transistors (P11, N25 and N26). Transistor (P10) is coupled to a source voltage (VDD) and transistor (N26) is coupled to ground (VSS or GnD). The zero storage node output SN[0] is coupled to a gate terminal of the transistor (P10) and a gate terminal of the transistor (N26). A zero negative read wordline (NRWL0) is coupled to address a gate terminal of transistor (P11) and a zero read wordline (RWL0) is coupled to address a gate terminal of transistor N25. A node 504 is located between terminals of the transistor (P11) and transistor (N25) and is coupled to a zero-output stage 508 by way of node 506.

A first storage node output SN[1] is coupled to a first stage multiplexer circuit comprising first-input stage 510. First input stage 510 comprises transistor (P12) coupled in series with transistors (P13, N27 and N28). Transistor (P12) is coupled to a source voltage (VDD) and transistor (N28) is coupled to ground (VSS or GnD). The first storage node output SN[1] is coupled to a gate terminal of the transistor (P12) and a gate terminal of the transistor (N28). A first negative read wordline (NRWL1) is coupled to address a gate terminal of transistor (P13) and a first read wordline (RWL1) is coupled to address a gate terminal of transistor N27. A node 512 is located between terminals of the transistor (P13) and transistor (N28) and is coupled to the zero-output stage 508 by way of node 506.

A second storage node output SN[2] is coupled to a first stage multiplexer circuit comprising second-input stage 514. Second input stage 514 comprises transistor (P14) coupled in series with transistors (P15, N29 and N30). Transistor (P14) is coupled to a source voltage (VDD) and transistor (N30) is coupled to ground (VSS or GnD). The second storage node output SN[2] is coupled to a gate terminal of the transistor (P14) and a gate terminal of the transistor (N30). A second negative read wordline (NRWL2) is coupled to address a gate terminal of transistor (P15) and a second read wordline (RWL2) is coupled to address a gate terminal of transistor N29. A node 516 is located between terminals of the transistor (P15) and transistor (N29) and is coupled to the zero-output stage 508 by way of node 506.

A third storage node output SN[3] is coupled to a first stage multiplexer circuit comprising third-input stage 518. Third input stage 518 comprises transistor (P16) coupled in series with transistors (P17, N31 and N32). Transistor (P16) is coupled to a source voltage (VDD) and transistor (N32) is coupled to ground (VSS or GnD). The third storage node output SN[3] is coupled to a gate terminal of the transistor (P16) and a gate terminal of the transistor (N32). A third negative read wordline (NRWL3) is coupled to address a gate terminal of transistor (P17) and a third read wordline (RWL3) is coupled to address a gate terminal of transistor N31. A node 520 is located between terminals of the transistor (P17) and transistor (N32) and is coupled to the zero-output stage 508 by way of node 506.

The zero-output stage 508 comprises transistor (P18) coupled in series with transistors (P19, N33 and N34). Transistor (P18) is coupled to a source voltage VDD and transistor (N34) is coupled to ground (VSS or GnD). A zero negative read wordline bank (NRWL_BNK0) is coupled to address a gate terminal of transistor (N33) and a zero read wordline bank (RWL_BNK0) is coupled to address a gate terminal of transistor N33. A node 522 is located between terminals of the transistor (P19) and transistor (N33) and is coupled to a latch stage 526 by way of node 524. The latch stage 526 addresses node 524 by way of a read bitline (RBL).

The latch stage 526 comprises a read clock stage 528 comprising a transistor (P20) coupled in series with transistors (P21, N35 and N36). Transistor (P20) is coupled to a source voltage (VDD) and transistor (N36) is coupled to ground (VSS or GnD). Node 524 is connected to the read clock stage 528 between transistor (P21) and transistor (N35). A read clock signal is addressed to a gate terminal of the transistor (P21) and a negative read clock signal is addressed to a gate terminal of the transistor (N35). A gate terminal of the transistor (P20) and a gate terminal of the transistor (N36) is coupled to a Q stage (Q). The Q stage is the output of a storage node and is part of the circuit where the stored data can be accessed for further processing and in present techniques represents a 1 or a 0 stored bit. The Q stage comprises transistor (P22) and transistor (N37) coupled in series with the “Q” coupled between terminals of both transistors (P22 and N37). Transistor (P22) is coupled to a source voltage (VDD) and transistor (N37) is coupled to ground (VDD or GnD). Gate terminals of the transistor (P22) and transistor (N37) are connected to the read bitline which is configured to address the node 524.

A fourth storage node output SN[4] is coupled to a first stage multiplexer circuit comprising fourth-input stage 530. Fourth input stage 530 comprises transistor (P22) coupled in series with transistors (P23, N38 and N39). Transistor (P22) is coupled to a source voltage (VDD) and transistor (N39) is coupled to ground (VSS or GnD). The fourth storage node output SN[4] is coupled to a gate terminal of the transistor (P22) and a gate terminal of the transistor (N39). The zero negative read wordline (NRWL0) is coupled to address a gate terminal of transistor (P23) and the zero read wordline (RWL0) is coupled to address a gate terminal of transistor N38. A node 520 is located between terminals of the transistor (P23) and transistor (N38) and is coupled to a first-output stage 536 by way of node 534.

A fifth storage node output SN[5] is coupled to a first stage multiplexer circuit comprising a fifth-input stage 538. Fifth input stage 538 comprises transistor (P24) coupled in series with transistors (P25, N40 and N41). Transistor (P24) is coupled to a source voltage (VDD) and transistor (N41) is coupled to ground (VSS or GnD). The fifth storage node output SN[5] is coupled to a gate terminal of the transistor (P24) and a gate terminal of the transistor (N41). The first negative read wordline (NRWL1) is coupled to address a gate terminal of transistor (P25) and the first read wordline (RWL1) is coupled to address a gate terminal of transistor N40. A node 540 is located between terminals of the transistor (P25) and transistor (N40) and is coupled to the first-output stage 536 by way of node 534.

A sixth storage node output SN[6] is coupled to a first stage multiplexer circuit comprising sixth-input stage 542. Sixth input stage 542 comprises transistor (P26) coupled in series with transistors (P27, N42 and N43). Transistor (P26) is coupled to a source voltage (VDD) and transistor (N43) is coupled to ground (VSS or GnD). The sixth storage node output SN[6] is coupled to a gate terminal of the transistor (P26) and a gate terminal of the transistor (N43). The second negative read wordline (NRWL2) is coupled to address a gate terminal of transistor (P27) and the second read wordline (RWL2) is coupled to address a gate terminal of transistor N42. A node 544 is located between terminals of the transistor (P27) and transistor (N42) and is coupled to the first-output stage 536 by way of node 534.

A seventh storage node output SN[7] is coupled to a first stage multiplexer circuit comprising seventh-input stage 546. Seventh input stage 546 comprises transistor (P28) coupled in series with transistors (P29, N44 and N45). Transistor (P28) is coupled to a source voltage (VDD) and transistor (N45) is coupled to ground (VSS or GnD). The seventh storage node output SN[7] is coupled to a gate terminal of the transistor (P28) and a gate terminal of the transistor (N45). The third negative read wordline (NRWL3) is coupled to address a gate terminal of transistor (P29) and the third read wordline (RWL3) is coupled to address a gate terminal of transistor N44. A node 548 is located between terminals of the transistor (P29) and transistor (N44) and is coupled to the first-output stage 536 by way of node 534.

The first-output stage 536 comprises transistor (P30) coupled in series with transistors (P31, N46 and N47). Transistor (P30) is coupled to a source voltage VDD and transistor (N47) is coupled to ground (VSS or GnD). A first negative read wordline bank (NRWL_BNK1) is coupled to address a gate terminal of transistor (N31) and a first read wordline bank (RWL_BNK1) is coupled to address a gate terminal of transistor N46. A node 550 is located between terminals of the transistor (P31) and transistor (N46) and is coupled to the latch stage 526 by way of node 524. The latch stage 526 addresses node 524 by way of a read bitline (RBL).

An eighth storage node output SN[8] is coupled to a first stage multiplexer circuit comprising eighth-input stage 552. Eighth input stage 552 comprises transistor (P32) coupled in series with transistors (P33, N48 and N49). Transistor (P32) is coupled to a source voltage (VDD) and transistor (N49) is coupled to ground (VSS or GnD). The eighth storage node output SN[8] is coupled to a gate terminal of the transistor (P32) and a gate terminal of the transistor (N48). The zero negative read wordline (NRWL0) is coupled to address a gate terminal of transistor (P33) and the zero read wordline (RWL0) is coupled to address a gate terminal of transistor N48. A node 554 is located between terminals of the transistor (P33) and transistor (N48) and is coupled to a second-output stage 558 by way of node 556.

A ninth storage node output SN[9] is coupled to a first stage multiplexer circuit comprising ninth-input stage 560. Ninth input stage 560 comprises transistor (P34) coupled in series with transistors (P35, N50 and N51). Transistor (P34) is coupled to a source voltage (VDD) and transistor (N51) is coupled to ground (VSS or GnD). The ninth storage node output SN[9] is coupled to a gate terminal of the transistor (P34) and a gate terminal of the transistor (N51). The first negative read wordline (NRWL1) is coupled to address a gate terminal of transistor (P35) and the first read wordline (RWL1) is coupled to address a gate terminal of transistor N50. A node 562 is located between terminals of the transistor (P35) and transistor (N50) and is coupled to the second-output stage 558 by way of node 556.

A tenth storage node output SN[10] is coupled to a first stage multiplexer circuit comprising tenth-input stage 564. Tenth input stage 564 comprises transistor (P36) coupled in series with transistors (P37, N52 and N53). Transistor (P36) is coupled to a source voltage (VDD) and transistor (N53) is coupled to ground (VSS or GnD). The tenth storage node output SN[10] is coupled to a gate terminal of the transistor (P37) and a gate terminal of the transistor (N52). The second negative read wordline (NRWL2) is coupled to address a gate terminal of transistor (P37) and the second read wordline (RWL2) is coupled to address a gate terminal of transistor N52. A node 566 is located between terminals of the transistor (P37) and transistor (N52) and is coupled to the second-output stage 558 by way of node 556.

An eleventh storage node output SN[11] is coupled to a first stage multiplexer circuit comprising eleventh-input stage 568. Eleventh input stage 568 comprises transistor (P38) coupled in series with transistors (P39, N54 and N55). Transistor (P38) is coupled to a source voltage (VDD) and transistor (N55) is coupled to ground (VSS or GnD). The eleventh storage node output SN[11] is coupled to a gate terminal of the transistor (P38) and a gate terminal of the transistor (N55). The third negative read wordline (NRWL3) is coupled to address a gate terminal of transistor (P39) and the third read wordline (RWL3) is coupled to address a gate terminal of transistor N54. A node 570 is located between terminals of the transistor (P39) and transistor (N54) and is coupled to the second-output stage 558 by way of node 556.

The second-output stage 558 comprises transistor (P40) coupled in series with transistors (P41, N56 and N57). Transistor (P40) is coupled to a source voltage VDD and transistor (N57) is coupled to ground (VSS or GnD). A second negative read wordline bank (NRWL_BNK2) is coupled to address a gate terminal of transistor (N41) and a second read wordline bank (RWL_BNK2) is coupled to address a gate terminal of transistor N56. A node 572 is located between terminals of the transistor (P41) and transistor (N56) and is coupled to the latch stage 526 by way of node 524. The latch stage 526 addresses node 524 by way of a read bitline (RBL).

A twelfth storage node output SN[12] is coupled to a first stage multiplexer circuit comprising twelfth-input stage 574. Twelfth input stage 574 comprises transistor (P42) coupled in series with transistors (P43, N58 and N59). Transistor (P42) is coupled to a source voltage (VDD) and transistor (N59) is coupled to ground (VSS or GnD). The twelfth storage node output SN[12] is coupled to a gate terminal of the transistor (P42) and a gate terminal of the transistor (N59). The zero negative read wordline (NRWL0) is coupled to address a gate terminal of transistor (P43) and the zero read wordline (RWL0) is coupled to address a gate terminal of transistor N58. A node 576 is located between terminals of the transistor (P43) and transistor (N58) and is coupled to a third-output stage 580 by way of node 578.

A thirteenth storage node output SN[13] is coupled to a first stage multiplexer circuit comprising thirteenth-input stage 582. Thirteenth input stage 582 comprises transistor (P44) coupled in series with transistors (P45, N60 and N61). Transistor (P44) is coupled to a source voltage (VDD) and transistor (N61) is coupled to ground (VSS or GnD). The thirteenth storage node output SN[13] is coupled to a gate terminal of the transistor (P44) and a gate terminal of the transistor (N61). The first negative read wordline (NRWL1) is coupled to address a gate terminal of transistor (P45) and the first read wordline (RWL1) is coupled to address a gate terminal of transistor N60. A node 584 is located between terminals of the transistor (P45) and transistor (N60) and is coupled to the third-output stage 580 by way of node 578.

A fourteenth storage node output SN[14] is coupled to a first stage multiplexer circuit comprising fourteenth-input stage 586. Fourteenth input stage 586 comprises transistor (P46) coupled in series with transistors (P47, N62 and N63). Transistor (P46) is coupled to a source voltage (VDD) and transistor (N63) is coupled to ground (VSS or GnD). The fourteenth storage node output SN[14] is coupled to a gate terminal of the transistor (P46) and a gate terminal of the transistor (N63). The second negative read wordline (NRWL2) is coupled to address a gate terminal of transistor (P47) and the second read wordline (RWL2) is coupled to address a gate terminal of transistor N62. A node 588 is located between terminals of the transistor (P47) and transistor (N62) and is coupled to the third-output stage 580 by way of node 578.

A fifteenth storage node output SN[15] is coupled to a first stage multiplexer circuit comprising fifteenth-input stage 590. Fifteenth input stage 590 comprises transistor (P48) coupled in series with transistors (P49, N64 and N65). Transistor (P48) is coupled to a source voltage (VDD) and transistor (N65) is coupled to ground (VSS or GnD). The fifteenth storage node output SN[15] is coupled to a gate terminal of the transistor (P48) and a gate terminal of the transistor (N64). The third negative read wordline (NRWL3) is coupled to address a gate terminal of transistor (P49) and the third read wordline (RWL3) is coupled to address a gate terminal of transistor N64. A node 592 is located between terminals of the transistor (P49) and transistor (N64) and is coupled to the third-output stage 580 by way of node 578.

The third-output stage 580 comprises transistor (P50) coupled in series with transistors (P51, N66 and N67). Transistor (P50) is coupled to a source voltage VDD and transistor (N67) is coupled to ground (VSS or GnD). A third negative read wordline bank (NRWL_BNK3) is coupled to address a gate terminal of transistor (N51) and a third read wordline bank (RWL_BNK3) is coupled to address a gate terminal of transistor N66. A node 594 is located between terminals of the transistor (P51) and transistor (N66) and is coupled to the latch stage 526 by way of node 524. The latch stage 526 addresses node 524 by way of a read bitline (RBL).

In some techniques, each transistor in the multiple sets of transistors is implemented with an n-type transistor designated by a “N”, e.g. N15. In some techniques, each transistor in the multiple sets of transistors is implemented with a p-type transistor designated by a “P”, e.g. P4. However, other implementations and configurations can be used to achieve similar results such that each transistor can be implemented with p-type transistors or an n-type transistor.

The read multiplexer circuit provides a custom circuit to multiplex storage node (SN) of 16 rows of bitcell values. The read multiplexer circuit is a two-stage mux and latch with the first stage providing a Mux4:1 with storage nodes from 16 different rows and 4 read word lines to select. The second stage provides a Mux4:1 to the output of the first stage and 4 read word line bank (4 rwl_bnk) pair to select.

In a read cycle one of the mux-selects (RWL*/RWL_BANK*) is pulsed high whilst a keeper circuit is disabled to avoid contention. At the end of the read cycles, the keeper circuit is enabled to hold the state. In a write cycle all mux-selects (RWL*/RWL_BANK*) are disabled. The keeper circuit holds its previous value which blocks storage node toggling due to the write cycle. Such an arrangement reduces mux output glitching during write cycles and reduces write dynamic power.

Accordingly, present techniques provide a read multiplexer circuit for a memory array and a circuit for a multiport register file which spatially separates the read and write functions. Whilst embodiments provide for a memory architecture with eighteen read ports in a single macro, a person skilled in the art will understand that the architecture is scalable to add or remove read ports without modification of a bitcell. During a write operation, a storage node activity is blocked at the read multiplexer circuit which reduces power compared to known memory arrays. Due to the spatial separation of the read and write functions there is less coupling for critical timing signals such as on read word line (RWL) and write word line (WWL) and vice-versa. Additionally, coupling is reduced from read bit lines (RBL) and write bit lines (WBL).

The examples and conditional language recited herein are intended to aid the reader in understanding the principles of the present technology and not to limit its scope to such specifically recited examples and conditions. It will be appreciated that those skilled in the art may devise various arrangements which, although not explicitly described or shown herein, nonetheless embody the principles of the present technology and are included within its scope as defined by the appended claims.

Furthermore, as an aid to understanding, the above description may describe relatively simplified implementations of the present technology. As persons skilled in the art would understand, various implementations of the present technology may be of a greater complexity.

In some cases, what are believed to be helpful examples of modifications to the present technology may also be set forth. This is done merely as an aid to understanding, and, again, not to limit the scope or set forth the bounds of the present technology. These modifications are not an exhaustive list, and a person skilled in the art may make other modifications while nonetheless remaining within the scope of the present technology. Further, where no examples of modifications have been set forth, it should not be interpreted that no modifications are possible and/or that what is described is the sole manner of implementing that element of the present technology.

Moreover, all statements herein reciting principles, aspects, and implementations of the technology, as well as specific examples thereof, are intended to encompass both structural and functional equivalents thereof, whether they are currently known or developed in the future. Thus, for example, it will be appreciated by those skilled in the art that any block diagrams herein represent conceptual views of illustrative circuitry embodying the principles of the present technology. Similarly, it will be appreciated that any flowcharts, flow diagrams, state transition diagrams, pseudo-code, and the like represent various processes which may be substantially represented in computer-readable media and so executed by a computer or processor, whether or not such computer or processor is explicitly shown.

### Clauses

1. A read multiplexer circuit for a multiport register file, comprising:
   an input stage coupled to an array of storage nodes, each storage node coupled to drive an output of a respective bitcell;
   a read stage comprising control logic dividing the array of storage nodes into one or more sets and first circuitry that provides a first read word line to a first storage node of a first set for reading data from the first storage node and a second read word line to a second storage node of the first set for reading data from the second storage node; and
   a first latch stage comprising second circuitry that provides a third read word line to the first and second storage node of the first set to latch the read from one of the first and second storage nodes.
2. A read multiplexer circuit as claimed in clause 1, wherein the first read word line is shared with a first storage node of a second set and the second read word line is shared with a second storage node of the second set for reading data from the first and second storage nodes of the second set respectively.
3. A read multiplexer circuit as claimed in any one of clauses 1 and 2, wherein the first read word line is shared with multiple sets of storage nodes and the second read word line is shared with multiple sets of storage nodes.
4. A read multiplexer circuit as claimed in any preceding clause, wherein the first circuitry that provides a first read word line to the first storage node comprises a first transistor and a second transistor coupled in series between a source voltage and a reference voltage.
5. A read multiplexer circuit as claimed in clause 4, wherein the first transistor is activated by the first read word line and the second transistor is activated by a logical inversion of the first read word line.
6. A read multiplexer circuit as claimed in clause 5, wherein a third transistor is coupled between the second transistor and the source voltage and a fourth transistor is coupled between the second transistor and the reference voltage.
7. A read multiplexer circuit as claimed in clause 6, the first latch stage comprising second circuitry such that the first read word line is coupled between the first transistor and the second transistor.
8. A read multiplexer circuit as claimed in clause 7, wherein the first latch stage is coupled to control logic that coordinates read operations provided by a read port line coupled from the first read stage to the control logic to determine an output state of stored data.
9. A read multiplexer circuit as claimed in any preceding clause, including a second latch stage comprising third circuitry that provides a fourth read word line to a first and second storage node of a different set to the first set to latch the read from one of the first and second storage nodes of that different set according to an address specifying a location of the storage node in the read multiplexer circuit.
10. A read multiplexer circuit as claimed in any preceding clause, comprising multiple sets and wherein each set is coupled to an individual latch circuit.
11. A read multiplexer circuit as claimed in any preceding clause, wherein an inverter is coupled to an output of a bitcell to drive storage node output of the bitcell.
12. A circuit for a multiport register file comprising:
   an array of multiple storage nodes, each having a bitcell;
   a two-stage read multiplexer circuit configured to receive an output of each storage node in the array of multiple storage nodes, comprising:
      a read stage for selecting data from the storage node output;
      a first latch stage for storing the selected data;
      control logic for coordinating read operations from multiple ports.
13. A circuit as claimed in clause 12, wherein a driver is coupled to the output of each storage node and coupled to an input of the two-stage read multiplexer circuit.
14. A circuit as claimed in clause 13, wherein the driver is provided by an inverter coupled to the output of a bitcell to drive storage node output of the bitcell.
15. A circuit as claimed in any one of clauses 12 to 14, including control logic dividing the array of storage nodes into sets and first circuitry that provides a first read word line to a first storage node of a first set for reading data from the first storage node and a second read word line to a second storage node of the first set for reading data from the second storage node.
16. A circuit as claimed in clause 15, wherein the first read word line is shared with multiple sets of storage nodes and the second read word line is shared with multiple sets of storage nodes.
17. A circuit as claimed in clause 16, wherein the first latch stage is coupled to control logic that coordinates read operations provided by a read port line coupled from the read stage to the control logic to determine an output state of stored data.
18. A circuit as claimed in any one of clauses 12 to 17, including a second latch stage comprising third circuitry that provides a fourth read word line to a first and second storage node of a different set to the first set to latch the read from one of the first and second storage nodes of that different set according to an address specifying a location of the storage node in the circuit.
19. A non-transitory computer-readable medium to store computer-readable code for fabrication of the circuitry of clauses 1 to 11.
20. A non-transitory computer-readable medium to store computer-readable code for fabrication of the circuitry of clauses 12 to 18.

It will be clear to one skilled in the art that many improvements and modifications can be made to the foregoing exemplary embodiments without departing from the scope of the present techniques.

What is claimed is:

1. A read multiplexer circuit for a multiport register file, comprising:
an input stage coupled to an array of storage nodes, each storage node coupled to drive an output of a respective bitcell;
a read stage comprising control logic dividing the array of storage nodes into one or more sets and first circuitry that provides a first read word line to a first storage node of a first set for reading data from the first storage node and a second read word line to a second storage node of the first set for reading data from the second storage node; and
a first latch stage comprising second circuitry that provides a third read word line to the first and second storage node of the first set to latch the read from one of the first and second storage nodes.

2. A read multiplexer circuit as claimed in claim 1, wherein the first read word line is shared with a first storage node of a second set and the second read word line is shared with a second storage node of the second set for reading data from the first and second storage nodes of the second set respectively.

3. A read multiplexer circuit as claimed in claim 1, wherein the first read word line is shared with multiple sets of storage nodes and the second read word line is shared with multiple sets of storage nodes.

4. A read multiplexer circuit as claimed in claim 1, wherein the first circuitry that provides a first read word line to the first storage node comprises a first transistor and a second transistor coupled in series between a source voltage and a reference voltage.

5. A read multiplexer circuit as claimed in claim 4, wherein the first transistor is activated by the first read word line and the second transistor is activated by a logical inversion of the first read word line.

6. A read multiplexer circuit as claimed in claim 5, wherein a third transistor is coupled between the second transistor and the source voltage and a fourth transistor is coupled between the second transistor and the reference voltage.

7. A read multiplexer circuit as claimed in claim 6, the first latch stage comprising second circuitry such that the first read word line is coupled between the first transistor and the second transistor.

8. A read multiplexer circuit as claimed in claim 7, wherein the first latch stage is coupled to control logic that coordinates read operations provided by a read port line coupled from the first read stage to the control logic to determine an output state of stored data.

9. A read multiplexer circuit as claimed in claim 1, including a second latch stage comprising third circuitry that provides a fourth read word line to a first and second storage node of a different set to the first set to latch the read from one of the first and second storage nodes of that different set according to an address specifying a location of the storage node in the read multiplexer circuit.

10. A read multiplexer circuit as claimed in claim 1, comprising multiple sets and wherein each set is coupled to an individual latch circuit.

11. A read multiplexer circuit as claimed in claim 1, wherein an inverter is coupled to an output of a bitcell to drive storage node output of the bitcell.

12. A circuit for a multiport register file comprising:
an array of multiple storage nodes, each having a bitcell;
a two-stage read multiplexer circuit configured to receive an output of each storage node in the array of multiple storage nodes, comprising:
a read stage for selecting data from the storage node output;
a first latch stage for storing the selected data;
control logic for coordinating read operations from multiple ports.

13. A circuit as claimed in claim 12, wherein a driver is coupled to the output of each storage node and coupled to an input of the two-stage read multiplexer circuit.

14. A circuit as claimed in claim 13, wherein the driver is provided by an inverter coupled to the output of a bitcell to drive storage node output of the bitcell.

15. A circuit as claimed in claim 13, including control logic dividing the array of storage nodes into sets and first circuitry that provides a first read word line to a first storage node of a first set for reading data from the first storage node and a second read word line to a second storage node of the first set for reading data from the second storage node.

16. A circuit as claimed in claim 15, wherein the first read word line is shared with multiple sets of storage nodes and the second read word line is shared with multiple sets of storage nodes.

17. A circuit as claimed in claim 16, wherein the first latch stage is coupled to control logic that coordinates read operations provided by a read port line coupled from the read stage to the control logic to determine an output state of stored data.

18. A circuit as claimed in claim 12, including a second latch stage comprising third circuitry that provides a fourth read word line to a first and second storage node of a different set to the first set to latch the read from one of the first and second storage nodes of that different set according to an address specifying a location of the storage node in the circuit.

19. A non-transitory computer-readable medium to store computer-readable code for fabrication of the circuitry of claim 1.

20. A non-transitory computer-readable medium to store computer-readable code for fabrication of the circuitry of claim 12.
